(19) United States
(12) Patent Application Publication
(10) Pub. No.: US 2009/0002939 A1
(43) Pub. Date: Jan. 1, 2009

(54) Systems and methods for fan speed optimization

(76) Inventors: Eric Baugh, Portland, OR (US); Himanshu Pokharna, Santa Clara, CA (US); Rajiv Mongia, Fremont, CA (US); Rafael de la Guardia, Providencia (MX); Willem M. Beltman, West Linn, OR (US); Robert J. Brennan, Portland, OR (US)

Correspondence Address: SCHUBERT, OSTERRIEDER & NICKELSON, PLLC;c/o Intellevate, LLC, P.O. BOX 52050, MINNEAPOLIS, MN, 55402, US

(21) Appl. No.: 11/824,371

(22) Filed: Jun. 29, 2007

(51) Int. Cl. H05K 7/20; H02P 5/00

(52) U.S. Cl. 361/687; 318/268; 361/695

(57) ABSTRACT

Systems and methods for controlling cooling fan speed based on ambient noise levels are disclosed. Some embodiments may include a method for controlling cooling fan speed. The method may include receiving an indication of a current ambient noise level at a computer system and predicting noise due to one or more cooling fans at an expected operator position for the computer system based on a first speed of the cooling fan(s). Embodiments of the method may also include comparing the predicted operation position noise due to the cooling fan(s) with the current ambient noise level and adjusting the cooling fan(s) to a second speed based on the comparison between the predicted operator position noise and the current ambient noise level. Other embodiments are disclosed and claimed.

### FIELD

Embodiments are in the field of cooling systems for electronic systems. More particularly, embodiments are in the field of cooling fans and cooling fan control systems for computer systems and other electronic systems.

### BACKGROUND

Many computer systems require various forms of cooling in order to maintain satisfactory levels of operation and reliability. This problem is often exacerbated in mobile computing systems as they are typically more compact than traditional systems, resulting in more difficulties in rejecting heat from the system. One common solution for cooling computer systems is to provide one or more cooling fans that direct air over hotter surfaces to capture heat from those surfaces and then reject the air from the system. Such cooling fans, however, often result in undesirable amounts of noise and, as processing power and cooling needs continue to increase, the mitigation of cooling fan noise becomes increasingly important. Another solution for alleviating overheating of computer systems is to shut down or reduce the capability of various components to reduce the heat they generate.

Users may also adjust how their computer system handles cooling via user-adjustable preferences for hardware operation, such as by lowering LCD brightness, throttling CPU performance or accelerating hard drive shut down during inactivity while the system is on battery power. A user may thus trade-off performance and noise for their particular needs and preferences by giving higher priority to noise or performance. This solution can be inefficient in that, for example, a user may request that noise be given a higher priority and thus cooling reduced, resulting in needless reduction in performance in response to the reduced cooling in situations where the noise reduction is not necessary.

### BRIEF DESCRIPTION OF THE DRAWINGS

Aspects of various embodiments will become apparent upon reading the following detailed description and upon reference to the accompanying drawings in which like references may indicate similar elements:

FIG. 1 depicts a block diagram illustrating a fan optimization system with a fan operation optimizer, a fan speed controller and fan, and a microphone according to various embodiments;

FIG. 2 depicts a block diagram of one embodiment of a computer system suitable for executing the fan optimization system according to some embodiments;

FIG. 3 depicts a flow diagram illustrating a method for controlling fan speed based on ambient noise levels according to various embodiments; and

FIG. 4 depicts a graph illustrating an example comparison between predicted fan noise level and ambient noise levels according to various embodiments.

### DETAILED DESCRIPTION OF EMBODIMENTS

The following is a detailed description of embodiments of the invention depicted in the accompanying drawings. The embodiments are introduced in such detail as to clearly communicate the invention. However, the embodiment(s) presented herein are merely illustrative, and are not intended to limit the anticipated variations of such embodiments; on the contrary, the intention is to cover all modifications, equivalents, and alternatives falling within the spirit and scope of the appended claims.

Various embodiments of the present invention provide systems and methods for controlling a cooling fan based on current ambient noise levels. The following description provides specific details of certain embodiments of the invention illustrated in the drawings to provide a thorough understanding of those embodiments. It should be recognized, however, that the present invention can be reflected in additional embodiments and may be practiced without some of the details in the following description. In other instances, well-known structures and functions have not been shown or described in detail to avoid unnecessarily obscuring the description of the embodiments of the invention. While specific embodiments will be described below with reference to particular configurations and systems, those of skill in the art will realize that embodiments of the present invention may advantageously be implemented with other substantially equivalent configurations and/or systems.

Generally speaking, systems and methods for controlling cooling fan speed based on ambient noise levels are disclosed. Some embodiments may include a method for controlling cooling fan speed. The method may include receiving an indication of a current ambient noise level at a computer system and predicting noise due to one or more cooling fans at an expected operator position for the computer system based on a first speed of the one or more cooling fans. Embodiments of the method may also include comparing the predicted operation position noise due to the one or more cooling fans with the current ambient noise level and adjusting the one or more cooling fans to a second speed based on the comparison between the predicted operator position noise and the current ambient noise level.

Other embodiments include a system for controlling fan speed based on ambient noise levels. Embodiments of the system may include a microphone to receive an indication of current ambient noise level and a fan speed controller to control operation of one or more cooling fans. Embodiments of the system may also include a fan operation analyzer to predict noise due to the one or more cooling fans at an expected operator position for the system and to compare the predicted operator position noise with the current ambient noise level. The fan operation analyzer may also determine a new speed for the one or more cooling fans based on the comparison between the predicted operator position noise and the current ambient noise level.

The disclosed systems and methods may provide for effective and efficient control of a cooling fan for a system such a computer system by taking advantage of ambient noise level information. According to some embodiments, by comparing the estimated noise from the fan at various speeds with the current ambient noise level, the fan speed may be set as high as possible without exceeding the ambient noise levels by a specified amount. A higher ambient noise level, for example, allows for acceptable noise from higher fan speeds (and thus additional cooling). The disclosed methods and system may also take advantage of the particular spectrum of ambient noise in determining acceptable noise levels and fan speeds.

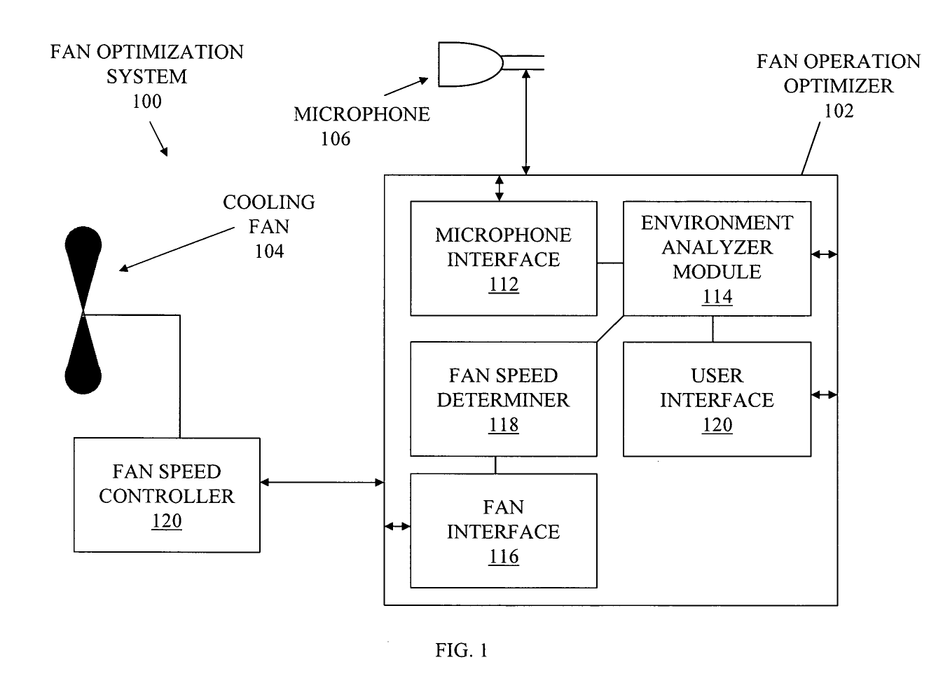

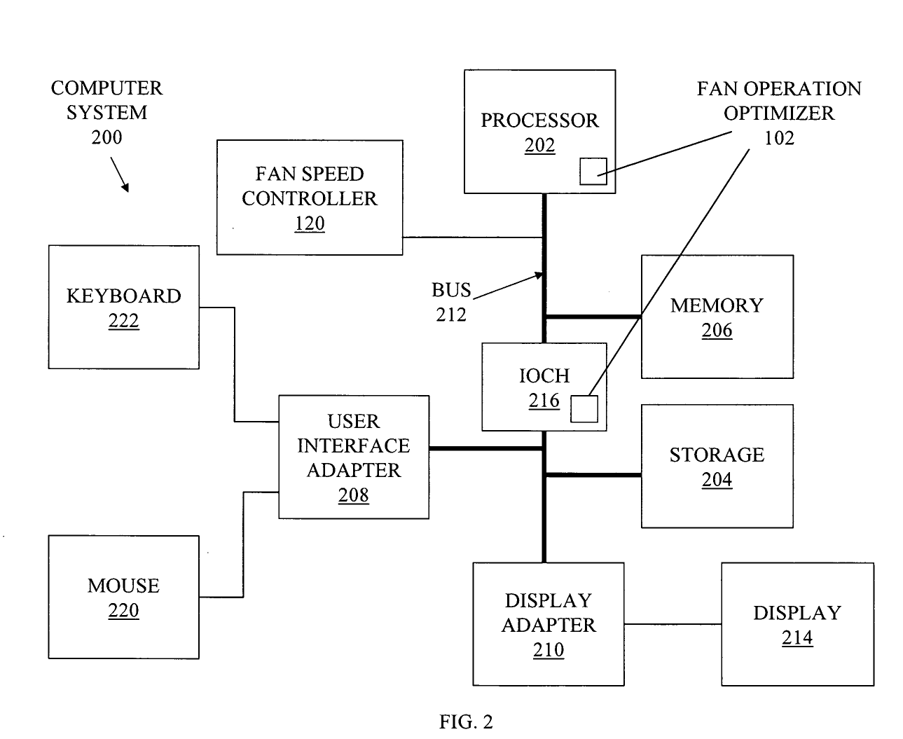

FIG. 1 depicts a block diagram illustrating a fan optimization system with a fan operation optimizer, a fan speed controller and fan, and a microphone according to various embodiments. In the fan optimization system 100 of FIG. 1, a fan operation optimizer 102 may be in communication with a cooling fan 104 (via a fan speed controller 120) and a microphone 106 or other audio recording device. The fan optimization system 100 of FIG. 1 and its components may be implemented on a computer system (as described in more detail in relation to FIG. 2) such as a desktop personal computer (PC) system or a mobile computer system such as a notebook or laptop PC.

As will be described in more detail subsequently, the fan operation optimizer 102 may receive indications of current ambient noise levels from the microphone 106 and may then compare those noise levels to a predicted noise level based on the speed of the cooling fan 104. The fan operation optimizer 102 may then adjust the cooling fan to a new speed based on the comparison between ambient noise level and predicted fan noise level so as to optimize fan speed while retaining desire noise characteristics. The fan operation optimizer 102 may then transmit an indication of the new fan speed to the fan speed controller 120, which in turn may command the cooling fan 104 to operate at the new speed.

The fan operation optimizer 102 may include components such as the microphone interface 112, an environment analyzer module 114, a fan interface 116, a fan speed determiner 118, and a user interface 120. One skilled in the art will recognize that while the components of the fan operation optimizer 102 are described separately, the functionality of each component may be combined in any fashion, such as by combining the functionality of two components into one. The microphone interface 112 may facilitate communication to and from the microphone 106, such as by receiving indications of a current ambient noise level from the microphone 106.

The fan interface 116 may facilitate communication between the fan operation optimizer 102 and the fan speed controller 120 (and thus the cooling fan 104). The fan interface 116 may, for example, transmit new desired fan speeds to the fan speed controller 120 or may receive indications of the current speed of the cooling fan 104. The fan speed determiner 118 may receive the indication of the current speed of the cooling fan 104 from the fan interface 116 and may use the indication to determine the actual speed of the cooling fan 104, if such a determination is required by other components of the fan operation optimizer 102. In some embodiments, the fan speed determiner 118 is not necessary and other components may use the indication of speed received from the fan speed controller 120 directly.

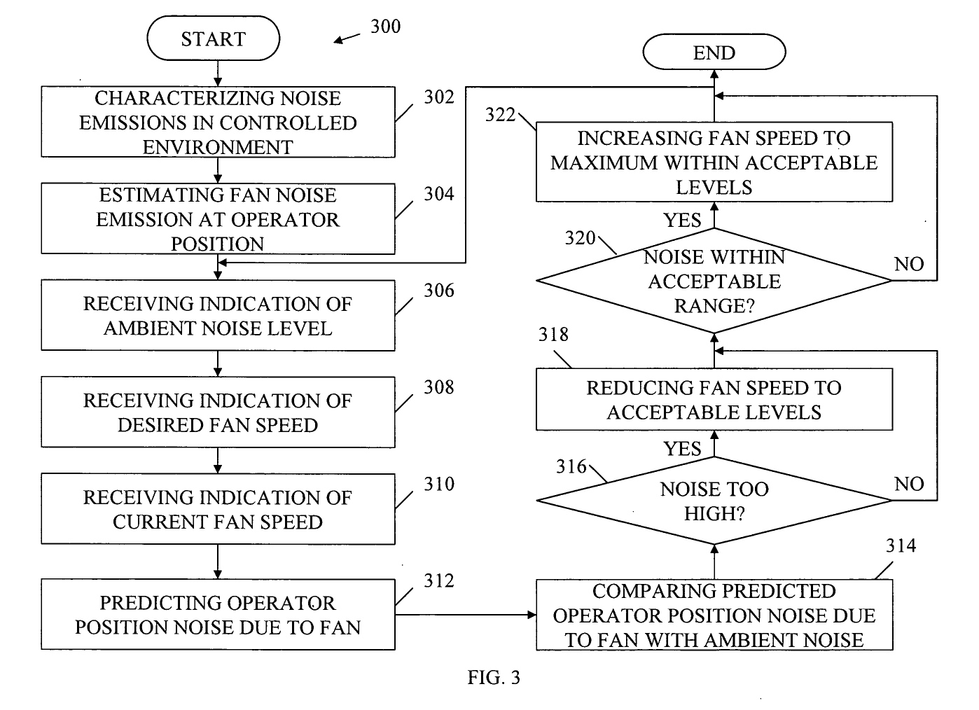

The environment analyzer module 114, as described in more detail in relation to FIG. 3, may predict the noise due to the cooling fan 104 at an expected operator position and may compare the predicted operator position noise with the current ambient noise level. The environment analyzer module 114 may utilize any metric to make its comparison, such as by comparing overall sound pressure level, sound pressure level by ⅓ octave spectrum, sound pressure level by Fast Fourier Transform (FFT) spectrum, or specific loudness, in increasing order of complexity. Sound pressure level may be considered to include any measurement or result that provides an indication of a level of sound, including both sound pressure level as is commonly used as well as indications of sound level that are not calibrated to sound pressure level but function similarly.

The predicted noise due to the cooling fan 104 may be the predicted noise at the expected location of the operator of the computer system, such as approximately two feet in front of a display screen. In an example embodiment, the expected operator position for a notebook computer system may be characterized as 25 centimeters horizontally and 45 centimeters vertically from the bottom front edge of the notebook housing. For a desktop computer system, determining an expected operator position can be more difficult as the location of the computer system relative to the operator may vary more, as the desktop computer system could be under a desk or on the top surface of the desktop, for example. For these embodiments, other methodologies such as statistical analysis (e.g., use top surface location if 65% of expected operators use it in this position) may be used to help determine an expected operator position. One of ordinary skill in the art will recognize that any type of methodology may be used to determine expected operator positions. Using the expected location of the operator may provide a more effective measurement than other locations since it is most likely to be relevant to a user (i.e., a user may typically be more concerned about noise levels for them instead of behind the computer).

Based on the results of the comparison between current ambient noise level and the predicted operator position noise, the environment analyzer module 114 may determine a new speed for the cooling fan 104 that more closely optimizes the fan speed by adjusting the speed to the maximum speed that still results in an acceptable noise level. For multiple cooling fan 104 systems, the environment analyzer module 114 may (depending on the number and configuration of cooling fans 104) determine a single speed for all of the cooling fans 104, speeds for only a subset of the cooling fans 104, different speeds for different cooling fans 104, or other configuration. The environment analyzer module 114 may then transmit an indication of the new cooling fan 104 speed to the fan interface 116 for further transmittal to the fan speed controller 120.

The user interface 120 may facilitate input and output to and from users, such as by receiving indications of user preferences for operation of the environment analyzer module 114. As will be described in more detail, users may optionally select preferences for one or more aspects of the disclosed system. A user, for example, may select a preference for the amount of acceptable noise they will hear from the cooling fan 104 at the selected fan speed. This preference may be in a variety of different forms, such as being expressed as an amount or percentage above or below existing ambient noise (for specific loudness), a number of decibels increase relative to ambient noise, or other metric. Users may also optionally select the frequency of new fan speed determinations, a different location for which to calculate estimated noise, or other operational aspects.

The components and features of the fan operation optimizer 102 may be implemented as software and/or firmware executing on one or more computer systems, such as those described in relation to FIG. 2. The components and features of the fan operation optimizer 102 may also be implemented using any combination of discrete circuitry, application specific integrated circuits (ASICs), logic gates and/or single chip architectures. Further, the features of the fan operation optimizer 102 may be implemented using microcontrollers, programmable logic arrays and/or microprocessors or any combination of the foregoing where suitably appropriate (collectively or individually referred to as “logic”).

The microphone 106 may be any audio recording device. In some embodiments, the microphone 106 may be included with the computer system when sold or leased as a standard audio recording device. In an alternative embodiment, multiple microphones 106 may be positioned in different locations in the computer system, providing the opportunity for a more sophisticated auditory map at the cost of increased complexity. The cooling fan 104 (of which there may be more than one) may be any type of fan utilized to direct air over or through components of the computer system, such as a cooling fan 104 typically included with a computer system when built. The fan speed controller 120 may control the state of the cooling fan 104, the speed of the cooling fan 104, the angle of attack of the fan blades, or any other aspect of the operation of the cooling fan 104.

As described previously, the disclosed systems may be particularly advantageous for mobile or portable computer systems as such systems are more likely to have increased cooling needs when compared to desktop systems because of their more compact packaging. Moreover, the operating environment of these systems are more likely to frequently change, making rough user configurations of fan speed less useful. The disclosed system may, for example, account for a user while in a quiet office environment (and lowering acceptable fan speeds) and while in a loud urban café environment (where fan speeds may be higher and still be acceptable). By automatically adjusting to changing environmental conditions, operation of the cooling fan 104 may be optimized.

An example system was created to demonstrate advantages that may be achieved with the disclosed system. The example entertainment PC desktop system was equipped with a low cost microphone 106. The demonstration system was a dual core system with background sensing implemented under a Linux kernel and an add-in card was used to read ambient noise sensor values. The demonstration system successfully used dynamic core migration and ambient sound pressure level sensing to switch a 100% load between the two cores while maintaining acceptable noise levels. Without the disclosed system, the demonstration system was forced to reduce its 100% load to 70% after approximately 50 seconds in order to keep fan speeds at a satisfactory level based solely on pre-determined allowable fan speeds.

FIG. 2 depicts a block diagram of one embodiment of a computer system 200 suitable for executing the fan optimization system 100 according to some embodiments. Other possibilities for the computer system 200 are possible, including a computer having capabilities other than those ascribed herein and possibly beyond those capabilities, and they may, in other embodiments, be any combination of processing devices such as workstations, servers, mainframe computers, notebook or laptop computers, desktop computers, PDAs, mobile phones, wireless devices, set-top boxes, or the like. At least certain of the components of computer system 200 may be mounted on a multi-layer planar or motherboard (which may itself be mounted on the chassis) to provide a means for electrically interconnecting the components of the computer system 200.

In the depicted embodiment, the computer system 200 includes a processor 202, storage 204, memory 206, a user interface adapter 208, a display adapter 210, and an Input/Output Controller Hub (IOCH) 216 connected to a bus 212 or other interconnect. The bus 212 facilitates communication between the processor 202 and other components of the computer system 200, as well as communication between components. Processor 202 may include one or more system central processing units (CPUs) or processors to execute instructions, such as an IBM® PowerPC™ processor, processors from Intel corporation (such as an Intel® Pentium® processor, an Intel® Itanium® 2 processor, an Intel® Xeon® processor), an Advanced Micro Devices Inc. processor or any other suitable processor. The processor 202 may utilize storage 204, which may be non-volatile storage such as one or more hard drives, tape drives, diskette drives, CD-ROM drive, DVD-ROM drive, or the like. The processor 202 may also be connected to memory 206 via bus 212, such as via a memory controller hub (MCH). System memory 206 may include volatile memory such as random access memory (RAM) or double data rate (DDR) synchronous dynamic random access memory (SDRAM). In the disclosed systems, for example, a processor 202 may execute instructions to perform functions of the fan operation optimizer 102, such as by comparing current ambient noise with predicted operator position noise to determine a new cooling fan 104 speed, and may temporarily or permanently store information during its calculations or results after calculations in storage 204 or memory 206. All or part of the fan operation optimizer 102, for example, may be stored in memory 206 during execution of its routines.

The user interface adapter 208 may connect the processor 202 with user interface devices such as a mouse 220 or keyboard 222. The user interface adapter 208 may also connect with other types of user input devices, such as touch pads, touch sensitive screens, electronic pens, microphones, etc. A user specifying their preferences, for example, may utilize the keyboard 222 and mouse 220 to interact with the computer system 200. The bus 212 may also connect the processor 202 to a display, such as an LCD display or CRT monitor, via the display adapter 210. An IOCH 216 may be designed to coordinate communications with various I/O devices, such as via the display adapter 210 or user interface adapter 208. In some embodiments, some or all of the functionality of the fan operation optimizer 102 may executed on the IOCH 216.

FIG. 3 depicts a flow diagram illustrating a method for controlling fan speed based on ambient noise levels according to various embodiments. Some or all of the elements of method 300 may be performed by components of the fan operation optimizer 102. Method 300 begins with optional elements 302 and 304 which together may be used to characterize the noise signature at an expected operator position of a particular system and cooling fan 104 combination at different fan speeds. At element 302, the fan operation optimizer 102 may characterize the noise emissions from the cooling fan 104 in a controlled environment by running the cooling fan 104 at various speeds for which characteristics are desired. A controlled environment such as an anechoic sound chamber may be used. At element 304, the fan operation optimizer 102 may estimate fan noise emission at the expected operator position. The expected operator position may be the position at which a user is most likely going to be hearing any noise generated by the cooling fan 104 (as described previously) while the user is using the computer system 200. In some embodiments, the expected operator position may be consistent with ergonomic standards promulgated by various organizations. Since the expected operator position is within the reverberation radius of a typical room environment, and there is no reverberation in an outdoor environment, the fan noise at the expected operator position may be effectively estimated by the direct field measurement in a controlled environment. According to some embodiments, the characterization of the cooling fan 104 noise at the expected operator position and at different cooling fan 104 speeds may be performed by a manufacturer, reseller, or other entity before the system is distributed to the user so that the fan optimization system 100 is ready for use upon receipt. The estimated characteristics may be stored for later use by the fan operation optimizer 102.

At element 306, the microphone interface 112 of the fan operation optimizer 102 may receive an indication of the current ambient noise level from the microphone 106. The indication of the current ambient noise level may be in any format. The indication of the current ambient noise level may also be in any type of metric, such as an overall sound pressure level, sound pressure level by ⅓ octave spectrum, sound pressure level by FFT spectrum, or specific loudness, in increasing levels of complexity. The more complex metrics may provide a more detailed and accurate description of the noise at the price of increased processing power required to later analyze them, and the metric chosen for any system may depend on user or manufacturer preference, capabilities of the microphone 106, or processing limitations.

The fan operation optimizer 102 may optionally receive an indication of a desired fan speed at element 308, such as by receiving such indication from a cooling system. The fan interface 116 of the fan operation optimizer 102 may receive at element 310 an indication of the current fan speed from the fan speed controller 120 and/or cooling fan 104. Using the indication of current fan speed, the fan speed determiner 118 may also determine the current speed of the cooling fan 104.

The environment analyzer module 114 may then at element 312 predict the noise due to the cooling fan 104 at the expected operator position based on the current fan speed and the estimated characteristics from elements 302 and 304. In one embodiment, the environment analyzer module 114 may predict the operator position noise by using a lookup table of fan speeds and expected operator position noise, while in other embodiments the environment analyzer module 114 may predict the operator position noise using more complex equations instead of a look-up table.

At element 314, the environment analyzer module 114 may compare the predicted operator position noise due to the cooling fan 104 with the current ambient noise level. As described previously, the environment analyzer module 114 may use any sort of metric to make the comparison, including making the comparison on the basis of overall sound pressure level, sound pressure level by ⅓ octave spectrum, sound pressure level by FFT spectrum, or specific loudness. The analysis may also be impacted by user preferences specifying the user's tolerance for noise, the level of cooling needed, or other factors. The environment analyzer module 114 may provide significant flexibility in comparing the two noise curves. The environment analyzer module 114 may, for example, require that the cooling fan 104 not be heard in a significant fashion by requiring that the predicted operator noise be below the current ambient noise level in all areas of the spectrum. In other embodiments, the environment analyzer module 114 may require that the predicted operator noise be below the current ambient noise level by a specified amount, such as by subtracting the two curves and integrating the difference to determine the relevant amount of cooling fan 104 noise. In these other embodiments, the environment analyzer module 114 may require that the estimated spectral curve of the predicted operator position noise be below the spectral curve of current ambient noise level by a pre-determined amount.

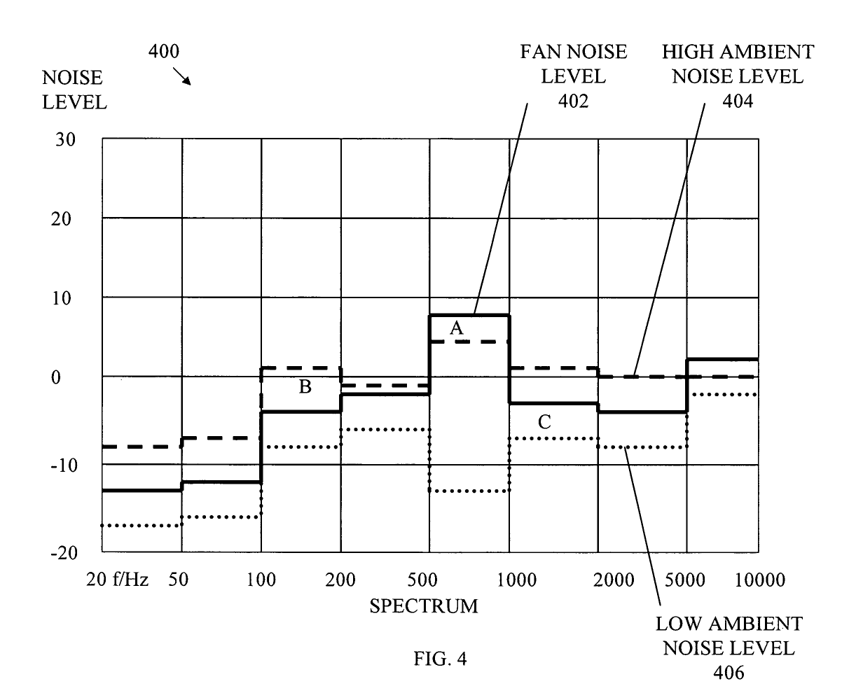

If the predicted operator position noise from the cooling fan 104 is too high at decision block 316, the fan operation analyzer 102 may reduce the fan speed to acceptable levels at element 318. In some embodiments, acceptable levels of predicted operator position noise may be thermally driven so that a very hot component that requires cooling may result in the fan staying at a high speed despite the predicted noise (i.e., placing a higher priority on cooling than noise). If the predicted operator position noise is within an acceptable range of the current ambient noise level at decision block 320, the fan operation analyzer 102 may increase the fan speed to a maximum within the acceptable levels at element 322, after which the method either terminates or returns to element 306 for continued processing. The cooling fan 104 speed may be advantageously increased in these situations because, if the ambient noise level is high in the regions of the spectrum where fan noise will be present, the cooling fan 104 may be run at a higher speed without the user or operator perceiving a substantial noise increase and thus improving cooling performance (as described in more detail in relation to FIG. 4).

FIG. 4 depicts a graph illustrating an example comparison between predicted fan noise level and ambient noise levels according to various embodiments. In the graph 400 of FIG. 4, the noise level is represented by the vertical axis and the different parts of the spectrum are represented by the horizontal axis. The predicted fan noise level 402 (solid line), an example high ambient noise level 404 (dashed line), and an example low ambient noise level 406 (dotted line) are depicted on graph 400. Generally speaking, in portions where the fan noise level curve 402 exceeds the ambient noise level curves the cooling fan 104 would be audible, and in portions where the fan noise level curve 402 is less than an ambient noise level curve the cooling fan 104 would be inaudible. When the two curves are close but the fan noise level curve 402 is still below, the cooling fan 104 would be audible to a greater or less extent depending on how close the fan noise level curve 402 was to the ambient noise level curve 404, 406. As described previously, the amount of excess noise above ambient due to fan operation can thus be computed for any fan speed which has been characterized by determining the amount that the fan noise level curve 402 exceeds ambient (such as by subtracting and integrating the two curves).

In the disclosed graph, the fan noise level curve 402 only exceeds the high ambient noise level 404 in one region (labeled region ‘A’). The cooling fan 104 may be operated at the speed associated with this curve, therefore, with only minimal audible impact on the user at the expected operator position. In other areas such as region ‘B’ the high ambient noise level curve 404 is higher than the predicted fan noise level curve 402, making the cooling fan 104 noise less intrusive or inaudible. In contrast, the predicted fan noise level curve 402 exceeds the low ambient noise level curve 406 in most areas (illustrated by region ‘C’), making this particular fan speed unlikely to satisfy most users as the cooling fan 104 would be very audible. The disclosed system may advantageously reduce the fan speed while in the low ambient noise level conditions to change the predicted fan noise level curve 402 to a lower curve that goes below the low ambient noise level curve 406 by a satisfactory amount.

As can be seen from the enclosed graph, the disclosed systems and methods may account for particular aspects of the ambient noise level. For example, if a high ambient noise level 404 has a peak noise level within the spectrum (region ‘A’) the particular shape of the predicted operator position noise may also be advantageously utilized if the two curves have similar peaks. A system that used a simple, flat noise level and ignored the particular spectrum may result in less advantageous fan speeds as the particular curves would have to be assumed in a worst-case fashion.

It will be apparent to those skilled in the art having the benefit of this disclosure that the present invention contemplates systems and methods for controlling a cooling fan based on ambient noise levels. It is understood that the form of the invention shown and described in the detailed description and the drawings are to be taken merely as examples. Although there have been described example embodiments of this novel invention, many variations and modifications are possible without departing from the scope of the invention. Accordingly the inventive embodiments are not limited by the specific disclosure above, but rather should be limited only by the scope of the appended claims and their legal equivalents. It is intended that the following claims be interpreted broadly to embrace all the variations of the example embodiments disclosed.

Various embodiments of the disclosed subject matter may be implemented in hardware, firmware, software, or combination thereof, and may be described by reference to or in conjunction with program code, such as instructions, functions, procedures, data structures, logic, application programs, design representations or formats for simulation, emulation, and fabrication of a design, which when accessed by a machine results in the machine performing tasks, defining abstract data types or low-level hardware contexts, or producing a result. Program code may be assembly or machine language, or data that may be compiled and/or interpreted. Furthermore, it is common in the art to speak of software, in one form or another as taking an action or causing a result. Such expressions are merely a shorthand way of stating execution of program code by a processing system which causes a processor to perform an action or produce a result.

Program code may be stored in, for example, volatile and/or non-volatile memory, such as storage devices and/or an associated machine readable or machine accessible medium including solid-state memory, hard-drives, floppy-disks, optical storage, tapes, flash memory, memory sticks, digital video disks, digital versatile discs (DVDs), etc., as well as more exotic mediums such as machine-accessible biological state preserving storage. A machine readable medium may include any mechanism for storing, transmitting, or receiving information in a form readable by a machine, and the medium may include a tangible medium through which electrical, optical, acoustical or other form of propagated signals or carrier wave encoding the program code may pass, such as antennas, optical fibers, communications interfaces, etc. Program code may be transmitted in the form of packets, serial data, parallel data, propagated signals, etc., and may be used in a compressed or encrypted format.

Program code may be implemented in programs executing on programmable machines such as mobile or stationary computers, personal digital assistants, set top boxes, cellular telephones and pagers, and other electronic devices, each including a processor, volatile and/or non-volatile memory readable by the processor, at least one input device and/or one or more output devices. Program code may be applied to the data entered using the input device to perform the described embodiments and to generate output information. The output information may be applied to one or more output devices. One of ordinary skill in the art may appreciate that embodiments of the disclosed subject matter can be practiced with various computer system configurations, including multiprocessor or multiple-core processor systems, minicomputers, mainframe computers, as well as pervasive or miniature computers or processors that may be embedded into virtually any device. Embodiments of the disclosed subject matter can also be practiced in distributed computing environments where tasks may be performed by remote processing devices that are linked through a communications network.

Although operations may be described as a sequential process, some of the operations may in fact be performed in parallel, concurrently, and/or in a distributed environment, and with program code stored locally and/or remotely for access by single or multi-processor machines. In addition, in some embodiments the order of operations may be rearranged without departing from the spirit of the disclosed subject matter. Program code may be used by or in conjunction with embedded controllers. Unless contrary to physical possibility, the inventors envision the methods described herein: (i) may be performed in any sequence and/or in any combination; and (ii) the components of respective embodiments may be combined in any manner.

The present invention and some of its advantages have been described in detail for some embodiments. It should be understood that various changes, substitutions and alterations can be made herein without departing from the spirit and scope of the invention as defined by the appended claims. An embodiment of the invention may achieve multiple objectives, but not every embodiment falling within the scope of the attached claims will achieve every objective. Moreover, the scope of the present application is not intended to be limited to the particular embodiments of the process, machine, manufacture, composition of matter, means, methods and steps described in the specification. One of ordinary skill in the art will readily appreciate from the disclosure of the present invention that processes, machines, manufacture, compositions of matter, means, methods, or steps, presently existing or later to be developed are equivalent to, and fall within the scope of, what is claimed. Accordingly, the appended claims are intended to include within their scope such processes, machines, manufacture, compositions of matter, means, methods, or steps.

What is claimed is:

1. A method, comprising:
receiving an indication of a current ambient noise level at a computer system;
predicting noise due to one or more cooling fans at an expected operator position for the computer system based on a first speed of the one or more cooling fans;
comparing the predicted operator position noise due to the one or more cooling fans with the current ambient noise level; and
adjusting the one or more cooling fans to a second speed based on the comparison between the predicted operator position noise and the current ambient noise level.

2. The method of claim 1, further comprising:
characterizing noise emissions at one or more cooling fan speeds in a controlled environment; and
estimating cooling fan noise emission at the expected operator position for each of the one or more cooling fan speeds.

3. The method of claim 2, wherein predicting noise due to the cooling fan at the expected operator position based on the first speed of the one or more cooling fans comprises receiving an indication of a current fan speeds and determining the predicted noise due to the one or more cooling fans at the current fan speed based on the estimated cooling fan noise emissions.

4. The method of claim 1, wherein comparing the predicted operator position noise due to the one or more cooling fans with the current ambient noise level comprises comparing based on one or more of overall sound pressure level, sound pressure level by ⅓ octave spectrum, sound pressure level by Fast Fourier Transform (FFT) spectrum, or specific loudness.

5. The method of claim 1, wherein adjusting the one or more cooling fans to the second speed based on the comparison between the predicted operator position noise and the current ambient noise level comprises adjusting the one or more cooling fans to the second speed lower than the first speed in response to the predicted operator position noise being too high in comparison to the current ambient noise level.

6. The method of claim 1, wherein adjusting the one or more cooling fans to the second speed based on the comparison between the predicted operator position noise and the current ambient noise level comprises adjusting the one or more cooling fans to the second speed higher than the first speed in response to the predicted operator position noise being within an acceptable range in comparison to the current ambient noise level.

7. The method of claim 1, wherein adjusting the one or more cooling fans to the second speed based on the comparison between the predicted operator position noise and the current ambient noise level comprises adjusting the one or more cooling fans to the second speed that results in an estimated spectral curve of predicted operator position noise that is entirely below a spectral curve of current ambient noise level.

8. The method of claim 1, wherein adjusting the one or more cooling fans to the second speed based on the comparison between the predicted operator position noise and the current ambient noise level comprises adjusting the one or more cooling fans to the second speed that results in an estimated spectral curve of predicted operator position noise that is below a spectral curve of current ambient noise level by a pre-determined amount.

9. A system, comprising:
a microphone to receive an indication of a current ambient noise level;
a fan speed controller to control operation of one or more cooling fans; and
a fan operation analyzer to predict noise due to the one or more cooling fans at an expected operator position for the system, to compare the predicted operator position noise with the current ambient noise level, and to determine a new speed for the one or more cooling fans based on the comparison between the predicted operator position noise and the current ambient noise level.

10. The system of claim 9, wherein the fan operation analyzer transmits an indication of the determined new speed for the one or more cooling fans to the fan speed controller.

11. The system of claim 9, wherein the fan operation analyzer receives an indication of the current ambient noise level from the microphone.

12. The system of claim 9, wherein the fan operation analyzer predicts noise due to the one or more cooling fans at an expected operator position for the computer system based on a current speed for the one or more cooling fans.

13. The system of claim 9, wherein comparing the predicted operator position noise due to the one or more cooling fans with the current ambient noise level comprises comparing based on one or more of overall sound pressure level, sound pressure level by ⅓ octave spectrum, sound pressure level by Fast Fourier Transform (FFT) spectrum, or specific loudness.

14. The system of claim 9, wherein determining a new speed for the one or more cooling fans based on the comparison between the predicted operator position noise and the current ambient noise level comprises choosing the new speed that is faster than a current cooling fan speed in response to the predicted operator position noise being within an acceptable range in comparison to the current ambient noise level.

15. The system of claim 9, wherein determining a new speed for the one or more cooling fans based on the comparison between the predicted operator position noise and the current ambient noise level comprises choosing the new speed that is slower than a current cooling fan speed and that results in an estimated spectral curve of predicted operator position noise that is below a spectral curve of current ambient noise level by a pre-determined amount.
